(19) United States
(12) Patent Application Publication
(10) Pub. No.: US 2015/0287845 A1
(43) Pub. Date: Oct. 8, 2015

(54) PID-RESISTANT SOLAR CELL STRUCTURE AND FABRICATION METHOD THEREOF

(71) Applicant: TSEC Corporation, New Taipei City (TW)

(72) Inventors: Chih-Chiang Huang, Hsinchu City (TW); Chu-Han Hsu, New Taipei City (TW); Cheng-Yeh Yu, Hsinchu City (TW)

(73) Assignee: TSEC Corporation, New Taipei City (TW)

(21) Appl. No.: 14/243,872

(22) Filed: Apr. 2, 2014

(51) Int. Cl. H01L 31/0216

(52) U.S. Cl. CPC H01L 31/02168

(57) ABSTRACT

A solar cell structure includes a substrate, a doped emitter layer on a front side of the substrate, and an anti-reflection layer covering the doped emitter layer. The anti-reflection layer is a multi-layer structure including at least one ion diffusion barrier such as amorphous silicon film or a silicon-rich silicon nitride film directly covering the doped emitter layer.

### BACKGROUND OF THE INVENTION

1. Field of the Invention

The present invention relates generally to the field of solar cell technology and, more particularly, to a PID-resistant solar cell structure and fabrication method thereof.

2. Description of the Prior Art

Potential induced degradation (PID) refers to power loss in a solar photovoltaic module due to high negative voltage, high humidity and high temperature. PID effect is not uncommon in the actual operation of the solar power plant. However, it can cause serious or even more than 50% power attenuation of solar cell element, resulting in decreased power output of the entire plant.

Currently, the industry still has no standard for PID measurement. There are three commonly used methods for testing PID effect : 1) 85° C., 85% absolute humidity, apply a negative voltage of 1,000 V, stress 96 hours; 2) at room temperature environment, apply negative voltage 1,000 V, stress168 hours; 3) 60° C., 85% absolute humidity, apply negative voltage of 1,000 V, stress 168 hours.

To cope with the PID effect, solutions may include strengthened ground path from the system side (increase potential difference), or choosing packaging materials with higher impedance from the module end. According to the experimental data, the replacement of high-impedance packaging material can more effectively reduce the effects of PID. However, the drawback is the increased cost of the solar cell battery.

Therefore, there is a need to propose an improved PID-resistant solar cell structure and manufacturing method without the need to replace the EVA (polyethylene vinyl acetate) packaging materials. The method is compatible with standard solar cell fabrication process and no additional process steps are incorporated.

### SUMMARY OF THE INVENTION

It is one object of the invention to provide an improved solar cell structure to alleviate or eliminate PID effect, furthermore increasing the efficiency of the solar cell battery.

According to one embodiment of the invention, a solar cell structure includes a substrate, a doped emitter layer on a front side of the substrate, and an anti-reflection layer covering the doped emitter layer. The anti-reflection layer is a multi-layer structure including at least one ion diffusion barrier such as amorphous silicon film or a silicon-rich silicon nitride film directly covering the doped emitter layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 are schematic diagrams showing a fabrication method of making a solar cell in accordance with one embodiment of the invention.

FIG. 7 illustrates an anti-reflection layer having a multi-film structure.

FIG. 8 shows real PID test data.

### DETAILED DESCRIPTION

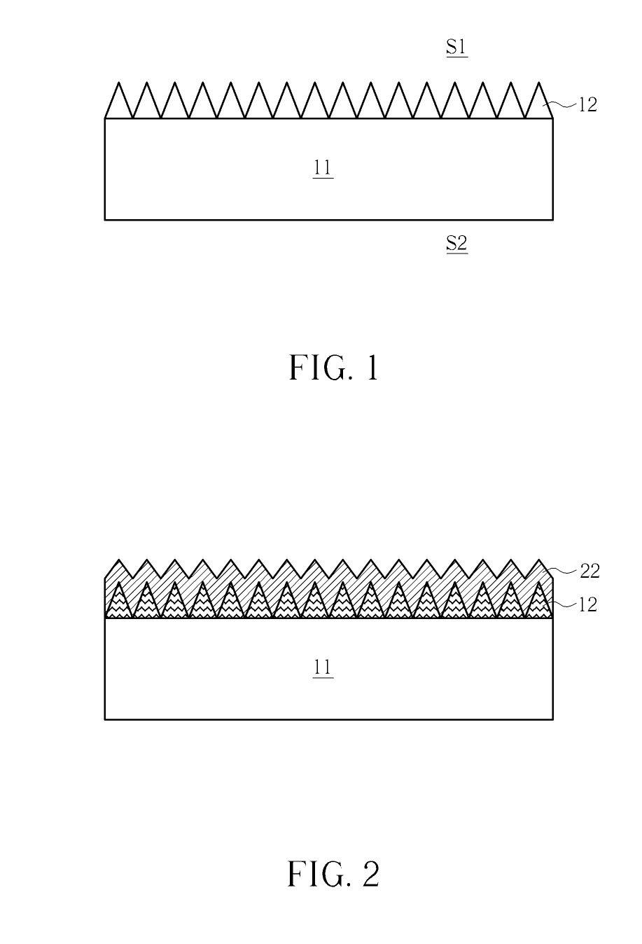

Please refer to FIG. 1 to FIG. 6. FIG. 1 to FIG. 6 are schematic diagrams showing a fabrication method of making a solar cell in accordance with one embodiment of the invention.

First, as shown in FIG. 1, a substrate 11 such as a P-type—silicon wafer is provided. The substrate 11 may be treated by a surface cleaning process and surface roughening process. The substrate 11 has a front side S1 and a rear side S2. The front side S1 may be a light receiving side.

Subsequently, as shown in FIG. 2, a doped emitter layer 12 is formed on the front side S1 of the substrate 11. For example, a phosphorus doped glass layer 22 is formed on the front side S1 of the substrate 11. A diffusion process implemented in a furnace may be carried out to form the doped emitter layer 12 on the front side S1 of the substrate 11. According to the embodiment of the invention, the doped emitter layer 12 is an N⁺ emitter layer. The temperature used in the aforesaid furnace may range between 800° C. and 850° C. for a time period of about 7-10 minutes. The doping concentration of the doped emitter layer 12 may range between 1E20 atoms/cm³ and 4E21 atoms/cm³ with a resistance ranging between 85Ω/sq and 65 Ω/sq.

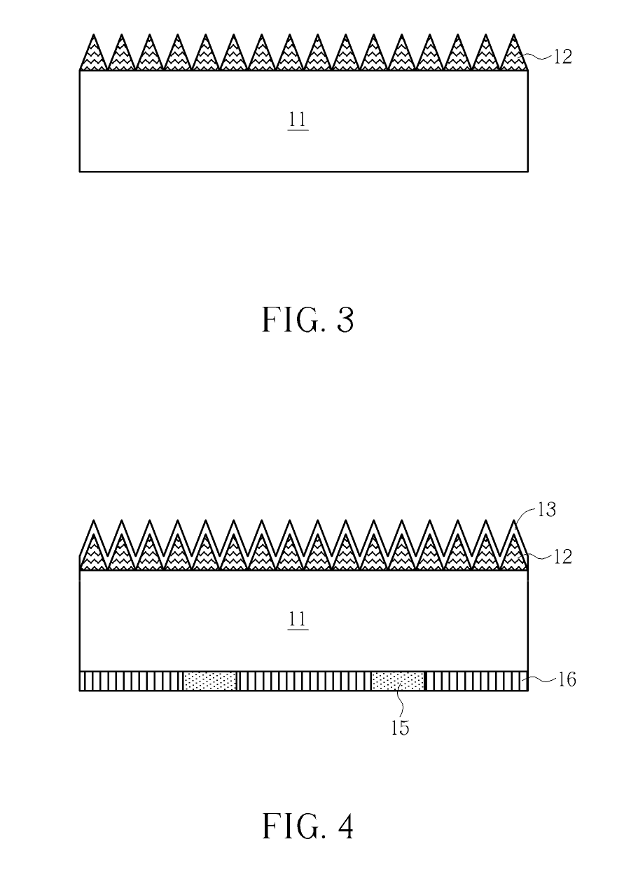

As shown in FIG. 3, an etching process such as a wet etching process or a dry etching process is performed to form wafer edge isolation. The phosphorus doped glass layer 22 is removed.

As shown in FIG. 4, a chemical vapor deposition (CVD) process such as a plasma-enhanced chemical vapor deposition (PECVD) process is carried out to deposit an anti-reflection layer 13 on the doped emitter layer 12. For example, the anti-reflection layer 13 may be composed of silicon nitride or silicon oxide. According to the embodiment, the anti-reflection layer 13 directly covers and is in direct contact with the doped emitter layer 12. According to the embodiment, the anti-reflection layer 13 may be a single film structure or a multi-film structure, for example, two-layered or three-layered film.

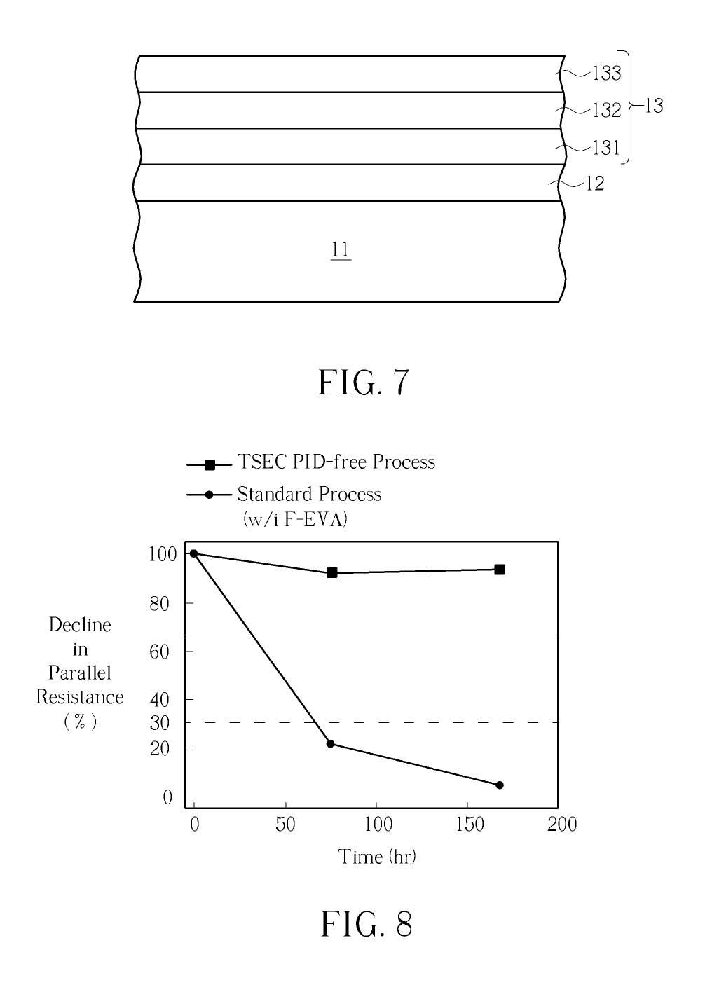

According to the embodiment, the anti-reflection layer 13 has a multi-film structure, as shown in FIG. 7, comprising at least one ion diffusion barrier 131 that has a densely packed structure to prevent sodium ions in the module glass from diffusing into the interface between the anti-reflection layer 13 and the doped emitted layer 12 such that the leakage path resulted from the sodium ions may be avoided.

Further, it is preferable to dispose the ion diffusion barrier 131 as the bottom layer of the multi-film structure of the anti-reflection layer 13. Preferably, the ion diffusion barrier 131 is in direct contact with the doped emitted layer 12. The anti-reflection layer 13 further comprises an upper layer 133 and a middle layer 132. The middle layer 132 is interposed between the upper layer 133 and the ion diffusion barrier 131. The upper layer 133 may comprise silicon nitride or silicon oxy-nitride and may have a thickness of about 50-150 nm. The middle layer 132 may comprise silicon nitride or silicon oxy-nitride and may have a thickness of about 50-80 nm.

According to the embodiment, the ion diffusion barrier 131 may comprise an amorphous silicon film, a silicon-rich silicon nitride film, a silicon-rich silicon oxide film or a silicon-rich silicon oxynitride film. In a case that the ion diffusion barrier 131 is a silicon-rich silicon nitride film, the CVD parameters for depositing such film may include: 1) process temperature: 400-450° C.; 2) power: 6000-8000 W; 3) SiH₄ flowrate: 600-2000 sccm; 4) NH₃ flowrate: 7-4 slm; and 5) N₂ flowrate: 5-10 slm, wherein the SiH₄ flowrate is about 12% to 40% of the total gas flowrate.

According to the embodiment, the ion diffusion barrier 131 may have a thickness of about 5-50 nm. Preferably, the thickness of the ion diffusion barrier 131 is smaller than that of the upper layer 133 or the middle layer 132 in order to maintain the optical characteristic of the anti-reflection layer 13. For example, the anti-reflection layer 13 as depicted in FIG. 7 may have a refraction index (n) of about 2.06±0.05 such that an optimal reflection rate may be obtained.

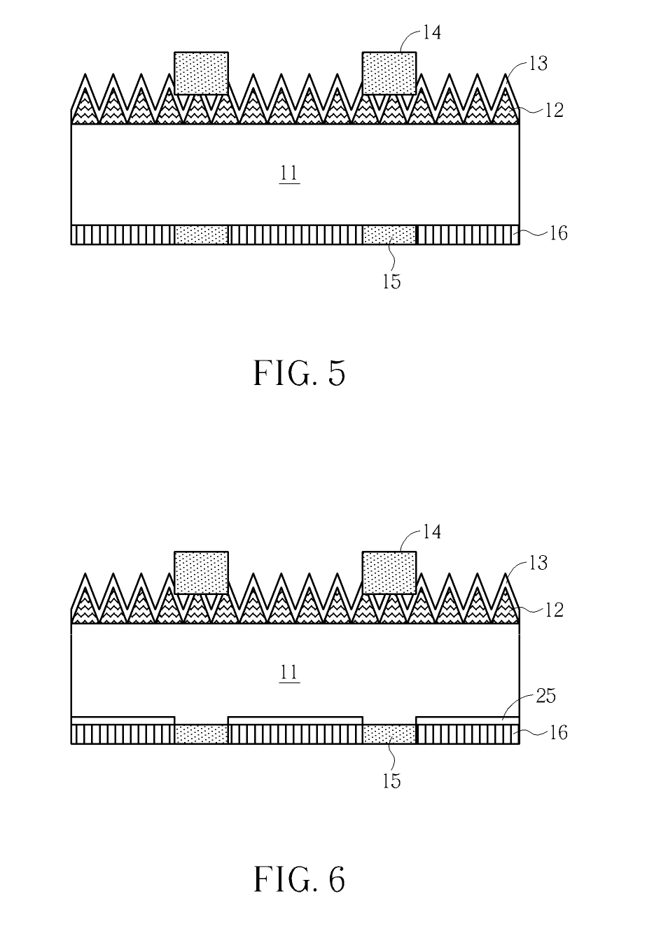

As shown in FIG. 5, a screen printing process maybe performed to form finger electrodes (not shown) and bus electrodes 14 on the front side S1 of the substrate 11. On the rear side S2, bus electrodes 15 and backside electrodes 16 are formed. According to the embodiment, the bus electrodes 14 and 15 may be composed of silver paste, while the backside electrode 16 may be composed of aluminum paste.

Finally, as shown in FIG. 6, a co-firing process may be performed to electrically couple the bus electrodes 14 with the doped emitted layer 12 and to form the P⁺ backside field layer 25 that is electrically coupled to the backside electrode 16.

It is advantageous to use the invention method because there is no need to replace the EVA packaging material in the module and no extra process steps are added to pass the PID test. As shown in FIG. 8, the difference can be seen according to the real PID test data, wherein the two tested modules both use Type F806 packaging material available from First.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A solar cell structure, comprising:
a substrate having a front side and a rear side;
a doped emitter layer on the front side of the substrate; and
an anti-reflection layer covering the doped emitter layer, wherein the anti-reflection layer at least comprises an ion diffusion barrier.

2. The solar cell structure according to claim 1 wherein the anti-reflection layer has a multi-film structure, and wherein the anti-reflection layer is located at a bottom of the multi-film structure, and is in direct contact with the doped emitter layer.

3. The solar cell structure according to claim 2 wherein the anti-reflection layer further comprises an upper layer and a middle layer that is interposed between the upper layer and the ion diffusion barrier.

4. The solar cell structure according to claim 3 wherein the upper layer comprises silicon nitride or silicon oxy-nitride.

5. The solar cell structure according to claim 4 wherein the upper layer has a thickness of about 50-150 nm.

6. The solar cell structure according to claim 3 wherein middle layer comprises silicon nitride or silicon oxy-nitride.

7. The solar cell structure according to claim 6 wherein the upper layer has a thickness of about 50-80 nm.

8. The solar cell structure according to claim 1 wherein the ion diffusion barrier comprises amorphous silicon.

9. The solar cell structure according to claim 1 wherein the ion diffusion barrier comprises a silicon rich silicon nitride film.

10. The solar cell structure according to claim 1 wherein the ion diffusion barrier comprises a silicon rich silicon oxide film.

11. The solar cell structure according to claim 1 wherein the ion diffusion barrier comprises a silicon rich silicon oxy-nitride film.

12. The solar cell structure according to claim 1 wherein the ion diffusion barrier has a thickness of about 5-50 nm.

13. The solar cell structure according to claim 3 wherein the anti-reflection layer has a refraction index (n) of about 2.06±0.05.

14. The solar cell structure according to claim 1 further comprising at least one bus electrode on the front side being electrically coupled to the doped emitter layer.

15. The solar cell structure according to claim 1 further comprising a backside electrode on the rear side and a backside field layer being electrically coupled to the backside electrode.

16. The solar cell structure according to claim 15 wherein the backside field layer is a P⁺ backside field layer.

17. The solar cell structure according to claim 1 wherein substrate is a P-type -silicon wafer and the doped emitter layer is an N⁺ emitter layer.
